(19) United States
(12) Patent Application Publication
(10) Pub. No.: US 2011/0062586 A1
(43) Pub. Date: Mar. 17, 2011

(54) Chip for Reliable Stacking on another Chip

(75) Inventors: Leo Lu, Taoyuan County (TW); Kuei-Wu Chu, Taoyuan County (TW); Jimmy Liang, Taoyuan County (TW)

(73) Assignee: MAO BANG ELECTRONIC CO., LTD., Taoyuan County (TW)

(21) Appl. No.: 12/814,458

(22) Filed: Jun. 13, 2010

(30) Foreign Application Priority Data
Sep. 17, 2009 (TW) 098217160

(51) Int. Cl. H01L 23/538

(52) U.S. Cl. 257/738; 257/E23.174

(57) ABSTRACT

A chip includes a device, a passivation layer, two dielectric layers, at least one upper redistribution layer, at least one lower redistribution layer, at least one tunnel, at least one conductor, a redistribution passivation layer and at least one solder ball. The device includes at least one pad. The tunnel is defined in the upper redistribution layer, the first dielectric layer, the passivation layer, the pad, the device, the chip, the second dielectric layer and the lower redistribution layer. The conductor is located in the tunnel and connected to the upper and lower redistribution layers. The redistribution passivation layer is located on the second dielectric layer, the lower redistribution layer and the conductor. The solder ball is located on a portion of the lower redistribution layer through an aperture defined in the redistribution passivation layer. The chip can be connected to a printed circuit board by the solder ball.

### BACKGROUND OF INVENTION

1. Field of Invention

The present invention relates to a chip and, more particularly, to a chip including at least one tunnel through which a layout on a face of the chip can reliably be connected to another layout on another face of the chip.

2. Related Prior Art

To make an integrated circuit (“IC”) element, an IC board is provided with a wiring region. According to the wiring region, devices are connected to one another by bonding. Finally, packaging is conducted. Thus, the IC element is finished and can be used in an electronic product. However, the devices require additional packaging to finish a required circuit, and the resultant integrated circuit element is therefore bulky and occupies a lot of precious space in the electronic product. This problem gets more and more serious as electronic products get smaller and smaller. Moreover, the IC element can only be used individually, i.e., several identical IC elements cannot be stacked.

Moreover, an IC is only formed on an active face of a chip. Terminals such as solder pads are only formed on the active face of the chip. In high-density electric connection technology, it is desirable to provide terminals not only on the active face but also on an opposite face of the chip to provide stacking and/or high-density packaging. Through silicon via (“TSV”) has been used as a vertical conductive path of a chip. The interior of the chip can be connected to the terminals on the faces of the chip due to the TSV. However, a process for making the TSV includes the steps of making masks, microlithography, sputtering, electroplating, packaging, and planting an array of solder balls. The process is complicated. The process is unstable since it is affected by many factors. Hence, the cost of the chip is high. Moreover, the TSV is located in a cut path and limited by the size of the cut path. Hence, it is difficult to make the TSV on a lateral face of the chip. Moreover, when the cutting of the chip is done, metal located in the TSV is exposed, and the circuit would be damaged. Moreover, the circuit must be extended to the lateral face of the chip, and the layout of the circuit is hence inflexible. Because of the possibility of the damage of the circuit, the yield of the chip is low, and the mass production of the chip is difficult. A chip with conventional TSB can be found in Taiwanese Patent No. 346117 issued to the applicant of the present application.

Referring to FIG. 7, a conventional IC element includes a first die 90 and a second die 94 provided on the first die 90. The first die 90 includes cutouts 91, a conductive region 92 and a wiring region 93. The conductive region 92 includes contacts 921. The wiring region 93 includes wires 931. Each of the wires 931 leads to a related one of the contacts 921 from a related one of the cutouts 91. The second die 94 includes cutouts 95, conductive media 96, a conductive region 97 and a wiring region 98. The conductive region 97 includes contacts 971. The wiring region 98 includes wires 981. Each of the wires 981 leads to a related one of the contacts 971 from a related one of the cutouts 95. Each of the conductive media 96 is filled in a related one of the cutouts 95. Thus, each of the contacts 971 is connected to a related one of the contacts 921.

The first die 90 is connected to the second die 94 because of the wires 931 and 931. However, the wires 931 and 981 must be extended throughout lateral faces of the dies 91 and 94, i.e., the cutouts 91 and 95. This is difficult. Moreover, the conductive media 96 are exposed and the circuit could hence be damaged. The yield in the production of the chip is low.

The present invention is therefore intended to obviate or at least alleviate the problems encountered in prior art.

### SUMMARY OF INVENTION

It is an objective of the present invention to provide a chip wherein the making of tunnels through which two faces of the chip is interconnected is not limited by the cutting of the chip from a wafer.

It is another objective of the present invention to provide a chip wherein interconnection of two faces of the chip is well protected.

It is another objective of the present invention to provide a chip with which the layout is flexible.

To achieve the foregoing objectives, the chip includes a device, a passivation layer, four dielectric layers, at least one upper redistribution layer, at least one lower redistribution layer, at least one tunnel, at least one conductor, a redistribution passivation layer and at least one solder ball. The device includes at least one pad formed thereon. The device is located on a face of the chip. The passivation layer is located on the device, with the pad accessible via an aperture defined therein. The first dielectric layer is located on the passivation layer, with the pad accessible through an aperture defined therein. The second dielectric layer is located on an opposite face of the chip. The third dielectric layer includes at least one redistribution aperture defined therein. The third dielectric layer is located on the first dielectric layer, with the pad accessible through the redistribution aperture thereof. The fourth dielectric layer includes at least one redistribution aperture defined therein. The fourth dielectric layer is located on the second dielectric layer. The upper redistribution layer is located in the redistribution aperture of the third dielectric layer. The lower redistribution layer is located in the redistribution aperture of the fourth dielectric layer. The tunnel is defined in the upper redistribution layer, the first dielectric layer, the passivation layer, the pad, the device, the chip, the second dielectric layer and the lower redistribution layer. The conductor is located in the tunnel and connected to the upper and lower redistribution layers. The redistribution passivation layer is located on the fourth dielectric layer, the lower redistribution layer and the conductor. The solder ball is located on a portion of the lower redistribution layer through an aperture defined in the redistribution passivation layer. The chip can be connected to a printed circuit board by the solder ball.

Other objectives, advantages and features of the present invention will be apparent from the following description referring to the attached drawings.

### BRIEF DESCRIPTION OF DRAWINGS

The present invention will be described via detailed illustration of the preferred embodiment versus the prior art referring to the drawings wherein:

FIG. 1 is a perspective view of a chip according to the preferred embodiment of the present invention;

FIG. 2 is another perspective view of the chip shown in FIG. 1;

FIG. 3 is a top view of the chip shown in FIG. 1;

FIG. 4 is a bottom view of the chip shown in FIG. 1;

FIGS. 5 through 9 are partial, cross-sectional views of semi-products of the chip shown in FIG. 1;

FIG. 10 is a partial, cross-sectional view of the final product of the chip shown in FIG. 1;

FIG. 11 is a partial, cross-sectional view of a printed circuit board connected to the chip shown in FIG. 10; and

FIG. 12 is a perspective view of a conventional stack of chips.

### DETAILED DESCRIPTION OF PREFERRED EMBODIMENT

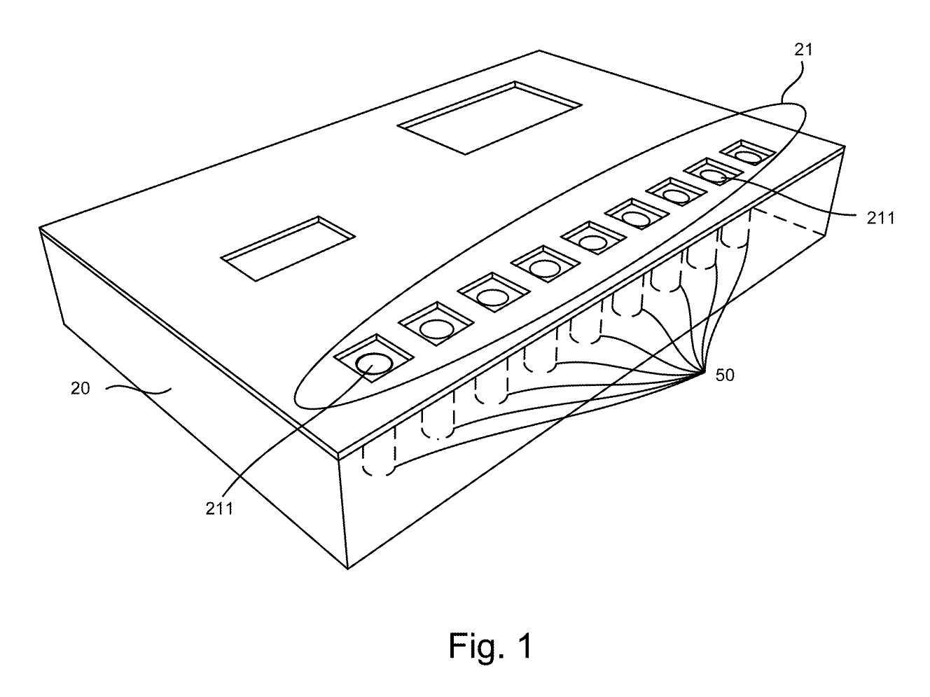

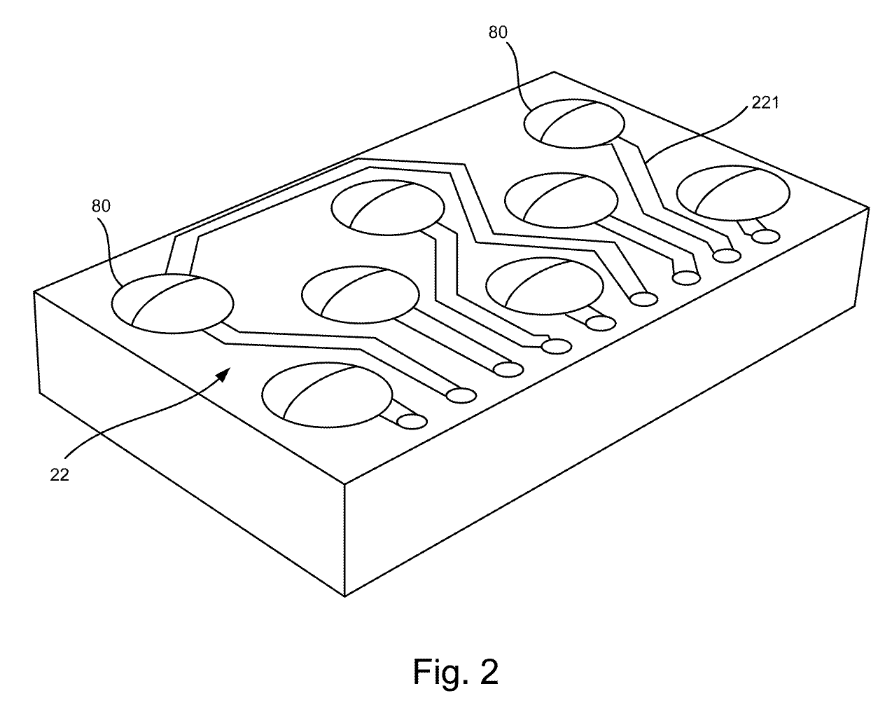

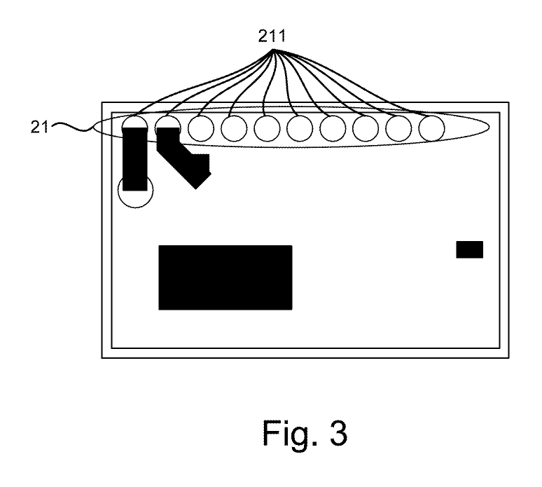

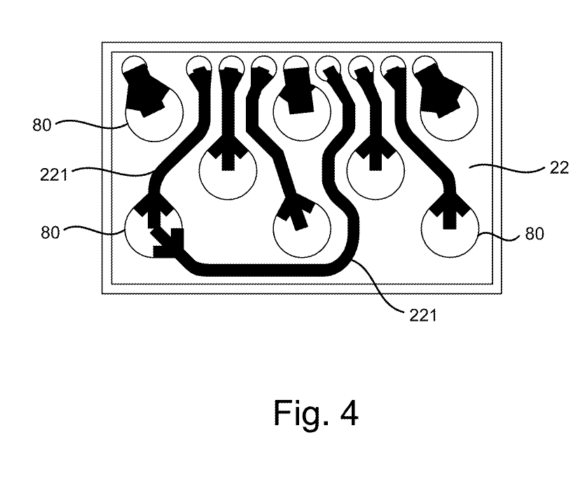

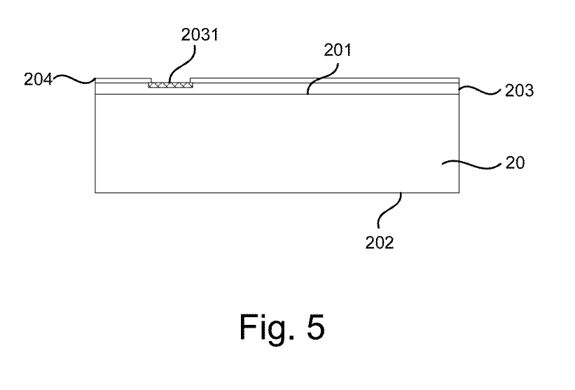

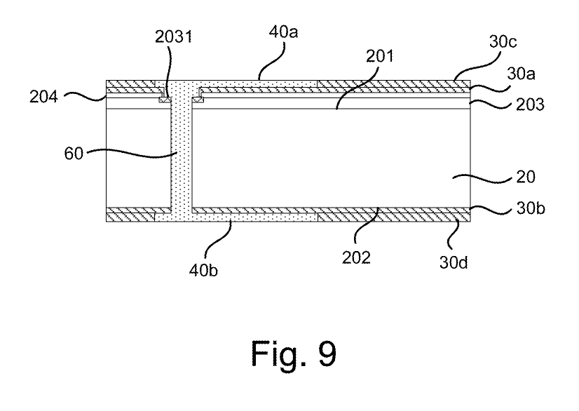

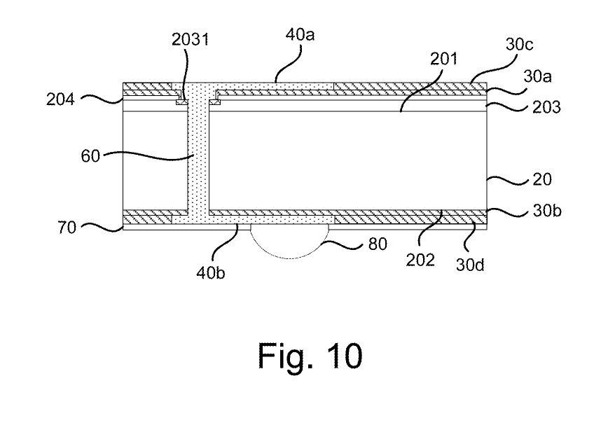

Referring to FIGS. 1 through 4, there is shown a chip 20 according to the preferred embodiment of the present invention. The chip 20 includes a conductive region 21 located on a first face 201 and a redistribution wiring region 22 located on a second face 202. The conductive region 21 includes contacts 221. The redistribution wiring region 22 includes wires 221. Tunnels 50 are defined in chip 20. Each of the contacts 21 is connected to a related one of the wires 221 by a conductor 60 (FIGS. 9 and 10) located in a related one of the tunnels 50. The production of the chip 20 will be described referring to FIGS. 5 through 10 wherein only a portion of the chip 20 around one of the tunnels 50 is shown.

Referring to FIG. 5, a device 203 is provided on the first face 201 of the chip 20. The device 203 is a transistor for example. The device 203 includes pads 2031 formed thereon although only one of the pads 2031 is shown. A passivation layer 204 is provided on the device 203. Each of the pads 2031 is accessible through a related one of apertures defined in the passivation layer 204.

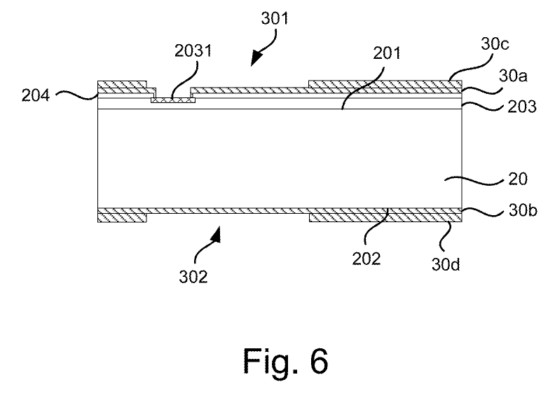

Referring to FIG. 6, there are provided four dielectric layers 30. The first one of the dielectric layers 30 (the “first dielectric layer 30a”) is located on the passivation layer 204 so that the pad 2031 is accessible through an aperture defined in the first dielectric layer 30a. The second one of the dielectric layers 30 (the “second dielectric layer 30b”) is located on the second face 202 of the chip 20. The third one of the dielectric layers 30 (the “third dielectric layer 30c”) includes redistribution apertures 301 defined therein although only one of the redistribution apertures 301 is shown. The third dielectric layer 30c is located on the first dielectric layer 30a while each of the pads 2031 is accessible through a related one of the redistribution apertures 301. The fourth one of the dielectric layers 30 (the “fourth dielectric layer 30d”) includes redistribution apertures 302 defined therein although only one of the redistribution apertures 302 is shown. The fourth dielectric layer 30d is located on the second dielectric layer 30b while portions of the second dielectric layer 30b are accessible through the redistribution apertures 302. The redistribution apertures 301 and 302 are made by drilling or punching for example.

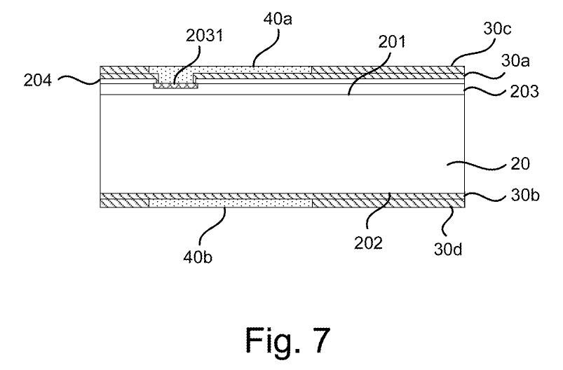

Referring to FIG. 7, there are provided redistribution layers 40 by electroplating or coated printing for example. The redistribution layers 40 include upper redistribution layers 40a (only one of them is shown) and lower redistribution layers 40b (only one of them is shown). The upper redistribution layers 40a are used as the contacts 211. Each of the upper redistribution layers 40a is located in a related one of the redistribution apertures 301 of the third dielectric layer 30c. Each of the pads 2031 is partially covered by a related one of the upper redistribution layer 40a.

The lower redistribution layers 40b are used as the wires 221. Each of the lower redistribution layers 40b is located in a related one of the redistribution apertures 302 of the fourth dielectric layer 30d.

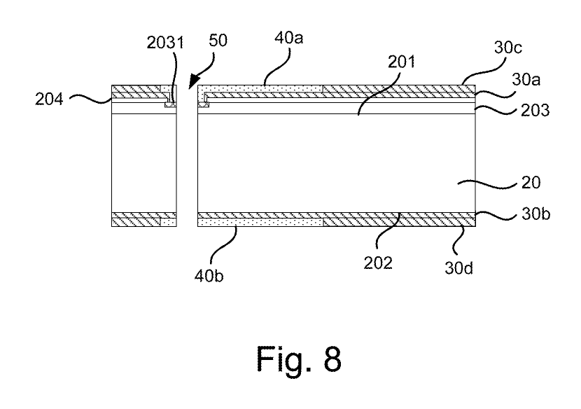

Referring to FIG. 8, the tunnels 50 are made by mechanical drilling or laser drilling. Each of the tunnels 50 extends through a related one of the upper redistribution layers 40a, the first dielectric layer 30a, the passivation layer 204, a related one of the pads 2031, the device 203, the chip 20, the fourth dielectric layer 30d and a related one of the lower redistribution layers 40b. The diameter of the tunnels 50 is smaller than that of the redistribution apertures 301 and 302.

Referring to FIG. 9, each of the conductors 60 is located in a related one of the tunnels 50 by electroplating or coated printing for example. Each of the conductors 60 includes an end connected to and in flush with a related one of the upper redistribution layers 40a and an opposite end connected to and in flush with a related one of the lower redistribution layers 40b. That is, the conductive region 21 is connected to the redistribution wiring region 22 through the conductors 60. The conductors 60 are made of metal such as gold, silver and copper.

Referring to FIG. 10, a redistribution passivation layer 70 is located on the fourth dielectric layer 30d, the lower redistribution layers 40b and the conductors 60. The redistribution passivation layer 70 includes apertures defined therein corresponding to the lower redistribution layers 40b.

There are provided solder balls 80. Each of the solder balls 80 is connected to at least one of the lower redistribution layers 40b by the surface mount technology (“SMT”) for example. Each of the solder balls 80 is located on a portion of a related one of the lower redistribution layers 40b through a related one of the apertures defined in the redistribution passivation layer 70.

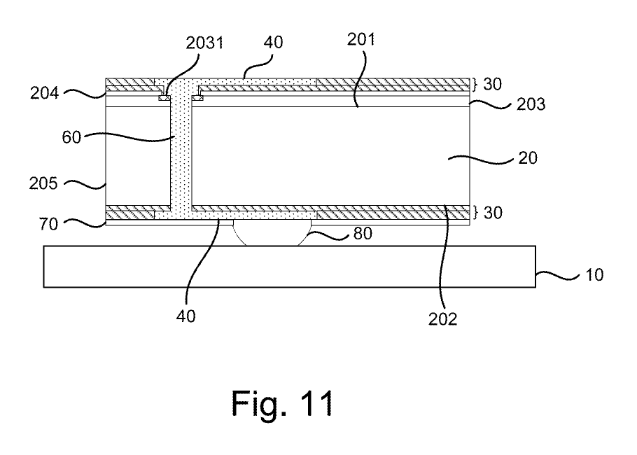

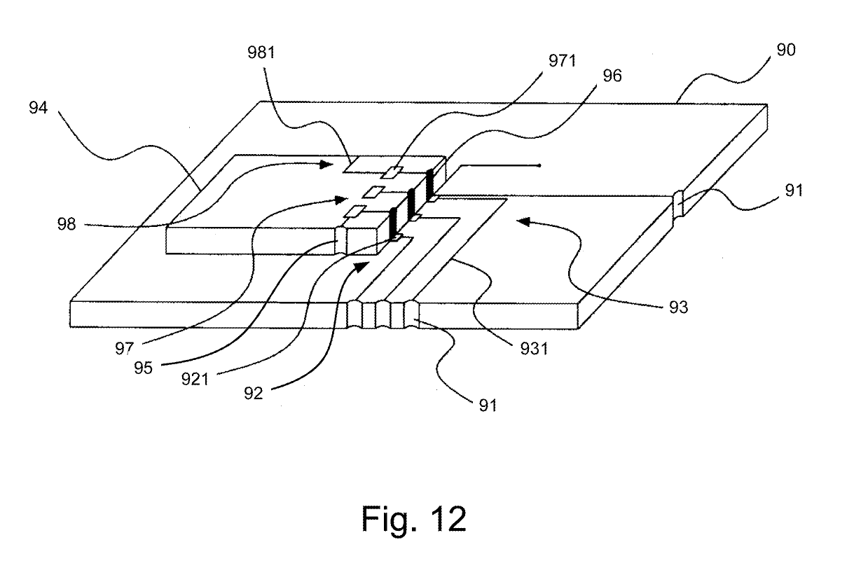

Referring to FIG. 11, the chip 20 can be connected to a printed circuit board 10 by the solder balls 80.

Initially, the chip 20 is made as a portion of a wafer. Later, the chip 20 is cut from the wafer. Advantageously, the chip 20 is not cut along a plane defined by the axes of the tunnels 50. Hence, the making of the apertures 50 is not limited by the cutting of the chip 20. Moreover, the conductors 60 are located in the tunnels 50. Therefore, the conductors 60 are well protected. Furthermore, the wires 221 do not extend on a lateral face or an edge of the chip 20. Hence, the electric properties of the chip 20 are excellent and the layout of the chip 20 is flexible.

The present invention has been described via the detailed illustration of the preferred embodiment. Those skilled in the art can derive variations from the preferred embodiment without departing from the scope of the present invention. Therefore, the preferred embodiment shall not limit the scope of the present invention defined in the claims.

1. An electronic stack, comprising:
a chip 20;
a device 203 includes at least one pad 2031 formed thereon, wherein the device 203 is located on a face 201 of the chip 20;
a passivation layer 204 located on the device 203, with the pad 2031 accessible via an aperture defined therein;
a first dielectric layer 30a located on the passivation layer 204, with the pad 2031 accessible through an aperture defined therein;
a second dielectric layer 30b located on an opposite face 202 of the chip 20;
a third dielectric layer 30c including at least one redistribution aperture 301 defined therein, wherein the third dielectric layer 30c is located on the first dielectric layer 30a, with the pad 2031 accessible through the redistribution aperture 301 thereof;
a fourth dielectric layer 30d including at least one redistribution aperture 302 defined therein, wherein the fourth dielectric layer 30d is located on the second dielectric layer 30b;
at least one upper redistribution layer 40a located in the redistribution aperture 301 of the third dielectric layer 30c;
at least one lower redistribution layer 40b located in the redistribution aperture 302 of the fourth dielectric layer 30d;
at least one tunnel 50 defined in the upper redistribution layer 40a, the first dielectric layer 30a, the passivation layer 204, the pad 2031, the device 203, the chip 20, the second dielectric layer 30b and the lower redistribution layer 40b;
at least one conductor 60 located in the tunnel 50 and connected to the upper and lower redistribution layers 40a, 40b;
a redistribution passivation layer 70 located on the fourth dielectric layer 30d, the lower redistribution layer 40b and the conductor 60; and
at least one solder ball 80 located on a portion of the lower redistribution layer 40b through an aperture defined in the redistribution passivation layer 70, wherein the chip 20 can be connected to a printed circuit board 10 by the solder ball 80.

2. The electronic stack according to claim 1, wherein the conductor 60 includes two ends in flush with the upper and lower redistribution layers 40a, 40b, respectively.

3. The electronic stack according to claim 1, wherein the conductor 60 is merged with the upper and lower redistribution layers 40a, 40b.

4. The electronic stack according to claim 1, wherein the diameter of the redistribution aperture 301 of the third dielectric layer 30c is larger than that of the tunnel 50.

5. The electronic stack according to claim 1, wherein the diameter of the redistribution aperture 302 of the fourth dielectric layer 30d is larger than that of the tunnel 50.
